(19) United States
(12) Patent Application Publication
(10) Pub. No.: US 2026/0234796 A1
(43) Pub. Date: Aug. 13, 2026

(54) METHOD OF MANUFACTURING MOLYBDENUM FILM

(71) Applicant: Samsung Electronics Co., Ltd., Suwon-si (KR)

(72) Inventors: Jeong Hwan Han, Seoul (KR); Ji Sang Ahn, Seoul (KR)

(73) Assignee: Foundation For Research and Business, Seoul National University of Science and Technology, Seoul (KR)

(21) Appl. No.: 19/439,012

(22) Filed: Jan. 2, 2026

(30) Foreign Application Priority Data
Feb. 7, 2025 (KR) 10 2025 0016170

(51) Int. Cl. C23C 16/455; C23C 16/44; C23C 16/56

(52) U.S. Cl. CPC C23C 16/45553; C23C 16/4408; C23C 16/56

(57) ABSTRACT

Provided is a method of manufacturing a molybdenum film by repeatedly performing a cycle, wherein the cycle includes preparing a substrate including a first region and a second region and injecting a molybdenum precursor onto the substrate, thereby forming a chemisorption layer of the molybdenum precursor, supplying a first purge gas onto a resulting structure in which the chemisorption layer of the molybdenum precursor has been formed, supplying a reducing agent containing water (H₂O) onto the chemisorption layer of the molybdenum precursor, thereby forming a molybdenum thin film, and supplying a second purge gas onto a resulting structure in which the molybdenum thin film has been formed.

### CROSS-REFERENCE TO RELATED APPLICATION

This application is based on and claims priority under 35 U.S.C. § 119 to Korean Patent Application No. 10-2025-0016170, filed on Feb. 7, 2025, in the Korean Intellectual Property Office, the disclosure of which is incorporated by reference herein in its entirety.

### BACKGROUND

Due to industrial advancements and demands for high-performance devices, semiconductor device manufacturing processes are becoming more intense and approaching physical limits. In order to manufacture such high-performance semiconductor devices, ALD, which forms a single atomic layer for each cycle, is increasingly being applied to manufacturing processes.

In ALD, unlike chemical vapor deposition (CVD), precursors and reactants are separated from each other in time and exposed to wafers. That is, the precursors and reactants are provided in sequential pulses and may not exist at the same time, and exhaust and purging operations may be performed to remove residual precursors and reactants between the pulses.

### SUMMARY

The present disclosure relates to a method of manufacturing a molybdenum film, and more particularly, to a method of manufacturing a molybdenum film by using atomic layer deposition (ALD).

Aspects of the present disclosure provide a method of manufacturing a molybdenum film that is formed at a relatively low process temperature and has relatively low resistivity.

Aspects of the present disclosure also provide a method of manufacturing a molybdenum film by using area-selective atomic layer deposition having a relatively low process difficulty.

The objects of the present disclosure are not limited to the aforementioned object, but other objects not described herein will be clearly understood by those skilled in the art from the following description.

According to an aspect of the present disclosure, there is provided a method of manufacturing a molybdenum film by repeatedly performing a cycle, wherein the cycle includes preparing a substrate including a first region and a second region and injecting a molybdenum precursor onto the substrate, thereby forming a chemisorption layer of the molybdenum precursor, supplying a first purge gas onto a first resulting structure in which the chemisorption layer of the molybdenum precursor has been formed, supplying a reducing agent containing water (H₂O) onto the chemisorption layer of the molybdenum precursor, thereby forming a molybdenum thin film, and supplying a second purge gas onto a second resulting structure in which the molybdenum thin film has been formed.

According to another aspect of the present disclosure, there is provided a method of manufacturing a molybdenum film by repeatedly performing a cycle, wherein the cycle includes injecting a bis(ethylbenzene)molybdenum (BEBMo) precursor onto a substrate including a first region and a second region, thereby forming a chemisorption layer of the BEBMo precursor, supplying a first purge gas onto a first resulting structure in which the chemisorption layer of the BEBMo precursor has been formed, supplying a reducing agent onto the chemisorption layer of the BEBMo precursor, thereby forming a molybdenum thin film, and supplying a second purge gas onto a second resulting structure in which the molybdenum thin film has been formed, wherein the first region of the substrate includes a conductive film, the second region of the substrate includes an insulating film, and the chemisorption layer of the BEBMo precursor is formed on the first region of the substrate.

According to another aspect of the present disclosure, there is provided a method of manufacturing a molybdenum film by repeatedly performing a cycle, wherein the cycle includes injecting a BEBMo precursor onto a substrate including a first region and a second region, thereby forming a chemisorption layer of the BEBMo precursor, supplying a first purge gas onto a first resulting structure in which the chemisorption layer of the BEBMo precursor has been formed, supplying a reducing agent containing water (H₂O) onto the chemisorption layer of the BEBMo precursor, thereby forming a molybdenum thin film, and supplying a second purge gas onto a second resulting structure in which the molybdenum thin film has been formed, wherein the first region of the substrate includes a conductive film, the second region of the substrate includes an insulating film, and the chemisorption layer of the BEBMo precursor has selectivity for the first region relative to the second region of the substrate until a specific number of the cycles at a specific process temperature.

### BRIEF DESCRIPTION OF THE DRAWINGS

Example implementations will be more clearly understood from the following detailed description taken in conjunction with the accompanying drawings in which:

FIG. 1 is a flowchart illustrating a method of manufacturing a molybdenum film, according to some implementations;

FIGS. 2A and 2B are cross-sectional views showing sequential manufacturing processes in a method of manufacturing a molybdenum film, according to some implementations;

FIG. 3 is a flowchart illustrating a method of manufacturing a molybdenum film, according to another implementation;

FIG. 4 is a graph showing results of X-ray photoelectron spectroscopy (XPS) to describe chemical compositions of a molybdenum film manufactured according to some implementations;

FIG. 5 is a graph showing changes in concentration over etch time to describe chemical compositions of a molybdenum film manufactured according to some implementations;

FIG. 6 is a graph showing resistivity according to a thickness of a molybdenum film manufactured according to some implementations;

FIGS. 7A to 7D are graphs showing a nucleation delay according to the number of cycles for each process temperature in an atomic layer deposition (ALD) process for forming molybdenum films;

FIGS. 8A to 8C are graphs showing areal selectivity according to the number of cycles for each process temperature in an ALD process for forming molybdenum films;

FIGS. 9A and 9B are graphs showing areal selectivity according to a thickness of a molybdenum film for each of materials constituting a first region and a second region of a substrate on which the molybdenum film is deposited in an ALD process for forming molybdenum films;

FIG. 10 is a graph showing current measured according to voltage on an insulating film to identify areal selectivity according to the number of cycles in an ALD process for forming molybdenum films;

FIG. 11 is a graph showing a height (a Z height) measured in an atomic force microscopy (AFM) image according to the number of cycles to identify areal selectivity in an ALD process for forming molybdenum films;

FIG. 12 is a graph showing results of Auger electron spectroscopy (AES) to identify areal selectivity in an ALD process for forming molybdenum films;

FIG. 13 is a graph showing results of X-ray diffraction (XRD) analysis to explain a crystalline phase of a molybdenum film that has been heat-treated under a hydrogen atmosphere;

FIG. 14 is a graph showing changes in concentration according to etch time to explain chemical compositions of a molybdenum film that has been heat-treated under a hydrogen atmosphere;

FIG. 15 is a graph showing resistivity according to a thickness of a molybdenum film that has been heat-treated under a hydrogen atmosphere; and

FIGS. 16A to 16C are transmission electron microscopy (TEM) images for identifying step coverage of a molybdenum film manufactured according to some implementations.

### DETAILED DESCRIPTION

Hereinafter, example implementations are described in detail with reference to the accompanying drawings. The same reference numerals are given to the same elements in the drawings, and repeated descriptions thereof are omitted.

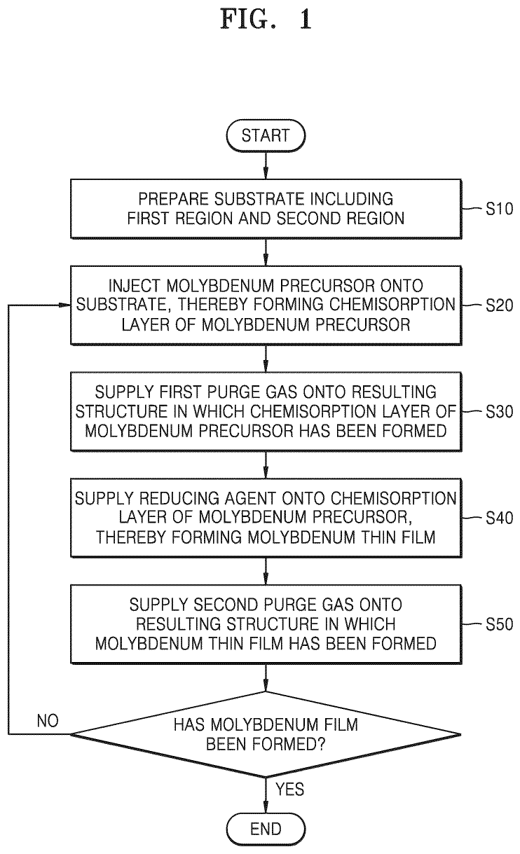

FIG. 1 is a flowchart illustrating a method of manufacturing a molybdenum film, according to some implementations.

Referring to FIG. 1, a substrate may be prepared first to manufacture a molybdenum film according to some implementations (S10). In some implementations, the substrate may include a first region and a second region. The first region may include a conductive film, and the second region may include an insulating film.

In some implementations, the conductive film may include metal, conductive metal nitride, conductive metal oxide, conductive metal oxynitride, metal silicide, or a combination thereof. For example, the conductive film may include tungsten, molybdenum, rubidium, titanium, cobalt, tantalum, nickel, tungsten silicide, titanium silicide, cobalt silicide, tantalum silicide, nickel silicide, or a combination thereof. For example, the conductive film may include NbN, TiN, CON, SnO₂, TaN, TiAlN, TaAIN, V, VN, Mo, MON, W, WN, Ru, RuO₂, SrRuO₃, Ir, IrO₂, Pt, PtO, SRO(SrRuO₃), BSRO((Ba,Sr)RuO₃), CRO(CaRuO₃), LSCO((La,Sr)CoO₃), or a combination thereof.

In some implementations, the insulating film may include a silicon oxide film, a silicon nitride film, insulating metal nitride, insulating metal oxide, insulating metal oxynitride, or a combination thereof. For example, the insulating film may include SiO₂, BN, AlN, TiO₂, Al₂O₃, or a combination thereof.

Subsequently, a first process may be performed to inject molybdenum precursors onto the substrate, thereby forming a chemisorption layer of the molybdenum precursors (S20). Then, a second process may be performed to supply a first purge gas onto the resulting structure in which the chemisorption layer of the molybdenum precursors has been formed (S30). The first purge gas may remove unnecessary by-products, including residual molybdenum precursors, which have not been adsorbed on the first region of the substrate. Next, a third process may be performed to supply reducing agents onto the chemisorption layer of the molybdenum precursors, thereby forming a molybdenum thin film (S40). Subsequently, a fourth process may be performed to supply a second purge gas onto the resulting structure in which the molybdenum thin film has been formed (S50). The second purge gas may remove unnecessary by-products including residual reducing agents.

In some implementations, the molybdenum precursors used in the first process may include bis(ethylbenzene)molybdenum (BEBMo) precursors. The reducing agents used in the third process described above may include water (H₂O). The first purge gas and the second purge gas used in the first process and the second process, respectively, may include inert gases, such as Ar, He, and Ne, or N₂.

In some implementations, the water (H₂O) is used as the reducing agents in an ALD process to form the molybdenum film. In this way, aspects of the present disclosure may provide a high-quality molybdenum film having relatively low resistivity and excellent step coverage at a relatively low process temperature. In experimental examples described below, molybdenum films (e.g., molybdenum carbide films or molybdenum carbonitride films) are formed by the ALD process using the BEBMo precursors, wherein reactants in addition to the water (H₂O) are used. Subsequently, properties of the thin films formed in the experimental examples are compared to each other.

### EXPERIMENTAL EXAMPLES

As shown in Table 1 below, the molybdenum films are deposited by using the BEBMo precursors and NH₃ plasma, the BEBMo precursors and NH₃ and H₂ plasma, and BEBMo precursors and Ru precursors, in addition to the BEBMo precursors and water (H₂O). This table relates to results of measuring resistivity, density based on X-ray reflectometry (XRR) (hereinafter, referred to as XRR density), chemical compositions, and step coverages of the deposited molybdenum films.

TABLE 1

| | Resistivity | XRR | Chemical composition | Step |
|---|---|---|---|---|
| Reactants | (μΩ × cm) | density | (at %) | coverage |
| NH₃ | 1,835 | 6.09 | Mo: 54, C: 8.5, N: 35, | 78.5% |
| plasma | | | O: 2.5 | |
| NH₃ | 389.7 | 8.56 | Mo: 53, C: 24.3, N: 21, | 68.9% |
| plasma + | | | O: 1.7 | |
| H₂ plasma | | | | |
| Ru | 1,182 | — | Mo: 36, C: 33, O: 25, | 78% |
| precursor | | | Ru: 6 | |
| H₂O | 172 to 334 | 8.4 | Mo: 67, C: 25, O: 8 | 92.2% |

Referring to the table above, when using the BEBMo precursor and NH₃ plasma, the BEBMo precursor and NH₃ and H₂ plasma, the short lifespans of the plasma reactants cause the reactants to fail to reach parts of a structure with a high aspect ratio and, thus, it can be seen that the step coverage is relatively low, i.e., in a range of about 69% to 79%. When using the BEBMo precursors and water (H₂O), it can be seen that the step coverage is relatively high at about 92%, compared to the other reactants. Also, when using the BEBMo precursors and water (H₂O), it can be seen that the molybdenum film has a relatively low ratio of impurities, such as oxygen (O), at 8 at %, and the molybdenum film has relatively low resistivity in a range of about 172 to 334, compared to the molybdenum films deposited by using the other reactants.

In some implementations, a cycle including the first process to the fourth process may be repeated multiple times so that the molybdenum film has a target thickness.

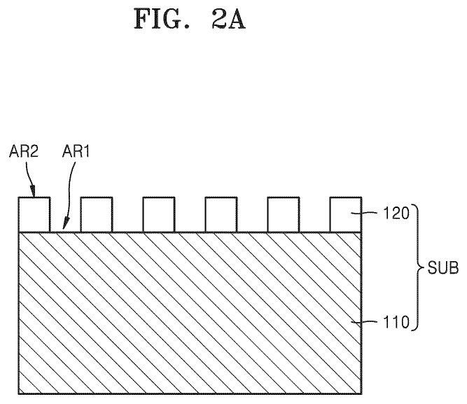

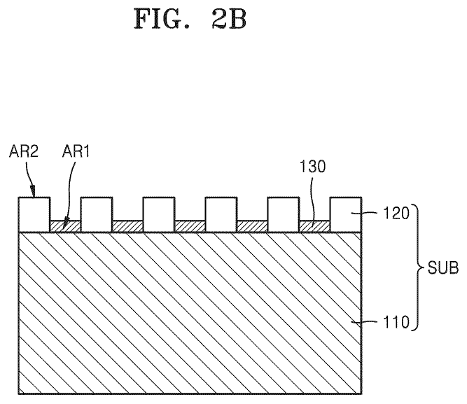

In some implementations, when the target thickness of the molybdenum film is less than or equal to a certain value, that is, when the cycle is repeatedly performed less than or equal to a certain number of times, the molybdenum film may be selectively formed only on the first region including the conductive film among the first region and the second region of the substrate. Without wishing to be bound by theory, it is believed that a nucleation delay occurs in the second region including the insulating film and, thus, the molybdenum film may have selectivity for the first region relative to the second region. However, in order for the molybdenum film to have the selectivity for the first region relative to the second region, the cycle may be repeated less than or equal to a certain number of times. The maximum number of repetitions of the cycle for the molybdenum film to have the selectivity for the first region relative to the second region may be determined by the process temperature, and the relationship between the maximum number of repetitions of the cycle and the process temperature is described in more detail with reference to FIGS. 2A and 2B.

In some implementations, the dose time of the BEBMo precursor in the first process may be about 10 seconds to about 30 seconds, the purge time of the first purge gas in the second process may be about 10 seconds to about 30 seconds, the dose time of the water (H₂O) in the third process may be about 5 seconds to about 20 seconds, and the purge time of the second purge gas in the fourth process may be about 10 seconds to about 30 seconds. For example, the dose time of the BEBMo precursor in the first process may be about 20 seconds to about 28 seconds, the purge time of the first purge gas in the second process may be about 16 seconds to about 24 seconds, the dose time of the water (H₂O) in the third process may be about 6 seconds to about 14 seconds, and the purge time of the second purge gas in the fourth process may be about 16 seconds to about 24 seconds. For example, the dose time of the BEBMo precursor in the first process may be about 24 seconds, the purge time of the first purge gas in the second process may be about 20 seconds, the dose time of the water (H₂O) in the third process may be about 10 seconds, and the purge time of the second purge gas in the fourth process may be about 20 seconds.

According to some implementations, the molybdenum film may be manufactured by using the BEBMo precursors and water (H₂O). In this case, although the process temperature for depositing the molybdenum film is relatively low in a range of about 150° C. to about 400° C., the molybdenum film may have relatively low resistivity in a range of about 100 μΩ×cm to about 600μΩ×cm and excellent the step coverage.

Also, a relatively high-quality molybdenum film may be provided, which contains about 60 at % to about 100 at % of molybdenum, about 20 at % to about 40 at % of carbon, and 0 at % to about 20 at % of oxygen.

FIGS. 2A and 2B are cross-sectional views showing sequential manufacturing processes in a method of manufacturing a molybdenum film, according to some implementations.

Referring to FIG. 2A, a substrate SUB may be provided. The substrate SUB may include a first region AR1 and a second region AR2 which are distinguished from each other. The first region AR1 of the substrate SUB may include a conductive film 110, and the second region AR2 thereof may include an insulating film 120.

In some implementations, the substrate SUB may include not only a structure in which a plurality of insulating films 120 are spaced apart from each other on the conductive film 110 as shown in the diagram, but also various structures including conductive films 110 and insulating films 120. For example, the substrate SUB may include a structure in which a plurality of conductive films 110 and a plurality of insulating films 120 are alternately arranged and overlap each other in a horizontal direction. For example, the substrate SUB may include a structure in which the plurality of conductive films 110 are spaced apart from each other on the insulating film 120.

Also, the substrate SUB may not only have a structure in which a stepped region exists between the upper surface of the conductive film 110 and the upper surface of the insulating film 120 as shown in the diagram, but also a structure in which there is no stepped region between the upper surface of the conductive film 110 and the upper surface of the insulating film 120 or a structure in which the upper surface of the conductive film 110 is at a lower vertical level than the upper surface of the insulating film 120.

Referring to FIG. 2B, the ALD process may be performed to selectively form a molybdenum film 130 on the first region AR1 among the first region AR1 and the second region AR2 of the substrate SUB. The ALD process may be performed by repeating the cycle that includes the first to fourth processes described with reference to FIG. 1.

In some implementations, the process temperature at which the first to fourth processes are performed may be about 200° C. to about 350° C. When the process temperature at which the first to fourth processes are performed is too low, the deposition efficiency of the BEBMo precursor may deteriorate. In addition, when the process temperature at which the first to fourth processes are performed is too high, it may be difficult to achieve selectivity for the first region AR1 relative to the second region AR2. Therefore, the process temperature at which the first to fourth processes are performed may be appropriate in a range of about 200° C. to about 350° C.

In some implementations, the process temperature at which the first to fourth processes are performed may be inversely proportional to the maximum number of repetitions of the cycle that includes the first to fourth processes having the selectivity for the first region AR1 relative to the second region AR2. In other words, as the process temperature at which the first to fourth processes are performed increases, the maximum number of repetitions of the cycle that includes the first to fourth processes having the selectivity for the first region AR1 relative to the second region AR2 may decrease.

When the process temperature is about 200° C. to about 350° C., the maximum number of repetitions of the cycle having the selectivity for the first region AR1 relative to the second region AR2 may be about 1 to about 60. For example, when the process temperature is about 200° C., the selectivity for the first region AR1 relative to the second region AR2 may be obtained when the number of repetitions of the cycle is about 1 to about 60. For example, when the process temperature is about 250° C., the selectivity for the first region AR1 relative to the second region AR2 may be obtained when the number of repetitions of the cycle is about 1 to about 40. For example, when the process temperature is about 300° C., the selectivity for the first region AR1 relative to the second region AR2 may be obtained when the number of repetitions of the cycle is about 1 to about 20. For example, when the process temperature is about 350° C., the selectivity for the first region AR1 relative to the second region AR2 may be obtained when the number of repetitions of the cycle is about 1 to about 10. Therefore, the maximum number of repetitions of the cycle that includes the first to fourth processes having the selectivity for the first region AR1 relative to the second region AR2 may be determined by the process temperature at which the first to fourth processes are performed.

Also, the cycle that includes the first to fourth processes may be repeated, less than or equal to the maximum number of repetitions determined by the process temperature, to form the molybdenum film having the target thickness. For example, at the process temperature of about 180° C. to about 220° C., the cycle may be repeated 50 times to 70 times to form the molybdenum film having a thickness of about 7 nm to about 9 nm. Also, the cycle may be repeated 30 times to 50 times to form the molybdenum film having a thickness of about 4 nm to about 7 nm. Also, the cycle may be performed 10 times to 30 times to form the molybdenum film having a thickness of about 2 nm to about 4 nm.

According to the related art, organic materials, such as self-assembled monolayers (SAMs) and small molecular inhibitors (SMIs), have been used so that materials may be adsorbed only on specific surfaces. However, when using these organic materials, the deposition time may increase and the deposition temperature may decrease due to the organic materials. In addition, the process difficulty may increase due to the additional process of adsorbing and then desorbing the SAMs and SMIs.

According to some implementations, the molybdenum film having the selectivity to the conductive film relative to the insulating film may be deposited under a certain number of repetitions of the cycle at a certain process temperature, even without the process of treating the surface of the substrate by using the organic materials, such as SAMs and SMIs. The characteristics of the molybdenum film formed by the manufacturing process of the molybdenum film, according to some implementations, are described in detail below.

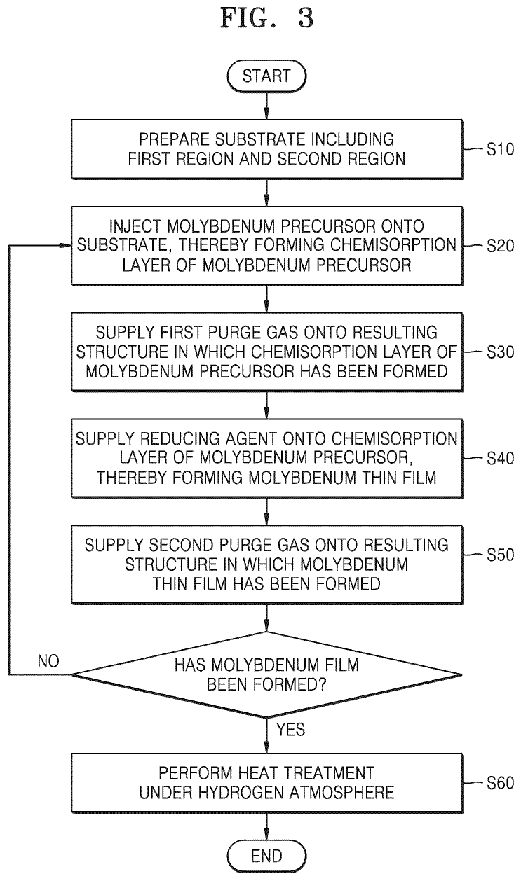

FIG. 3 is a flowchart illustrating a method of manufacturing a molybdenum film, according to another implementation.

The method of manufacturing the molybdenum film described with reference to FIG. 3 is generally similar to the method of manufacturing the molybdenum film described with reference to FIGS. 1, 2A, and 2B, but further includes performing heat treatment under a hydrogen atmosphere (S60). Therefore, the following description focuses on the differences therebetween.

Referring to FIG. 3, a substrate including a first region and a second region may be prepared (S10). Then, the molybdenum film may be formed by repeating a cycle that includes a first process of injecting molybdenum precursors onto the substrate, thereby forming a chemisorption layer of the molybdenum precursors (S20), a second process of supplying a first purge gas onto the resulting structure in which the chemisorption layer of the molybdenum precursors has been formed (S30), a third process of supplying reducing agents onto the chemisorption layer of the molybdenum precursors, thereby forming a molybdenum thin film (S40), and a fourth process of supplying a second purge gas onto the resulting structure in which the molybdenum thin film has been formed (S50). Subsequently, the molybdenum film may be heat-treated under the hydrogen atmosphere (S60).

The hydrogen atmosphere may contain about 5% to about 15% of hydrogen (H₂) gas and about 95% to about 85% of argon (Ar) gas. The process of heat-treating the molybdenum film under the hydrogen atmosphere may be performed at a maximum temperature of about 750° C. to about 850° C. under a pressure of about 6 torr to about 10 torr or about 7 torr to about 9 torr. Here, the heating rate from room temperature to the maximum temperature may be about 90° C./sec to about 110° C./sec, and the heat treatment time may be about 170 seconds to about 200 seconds, for example, 180 seconds. The molybdenum film may be subjected to heat treatment in the hydrogen atmosphere to reduce the molybdenum film. For example, carbon contained in the molybdenum film may be reduced and thereby removed from the molybdenum film.

According to some implementations, the molybdenum film that is heat-treated under the hydrogen atmosphere may have a relatively high molybdenum (Mo) ratio from about 95 at % to about 100 at % and a relatively low oxygen (O) ratio from 0 at % to about 5 at % in the chemical compositions of the molybdenum film, compared to the molybdenum film that is not heat-treated under the hydrogen atmosphere. Therefore, a relatively high-quality molybdenum film may be obtained.

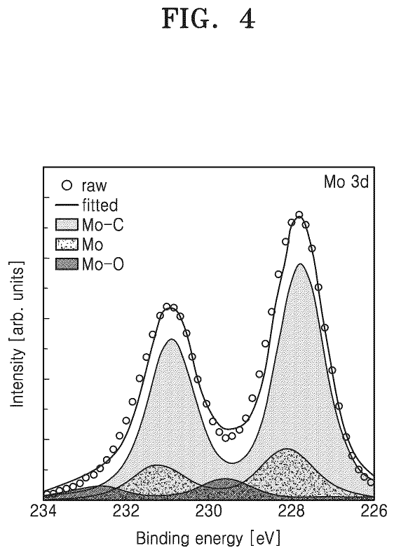

FIG. 4 is a graph showing results of X-ray photoelectron spectroscopy (XPS) to describe the chemical compositions of the molybdenum film manufactured according to some implementations.

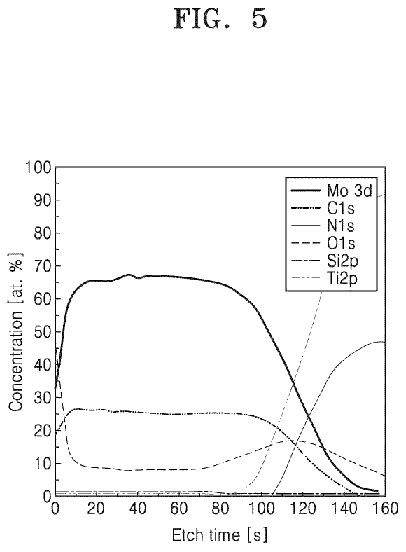

FIG. 5 is a graph showing changes in concentration over etch time to describe the chemical compositions of the molybdenum film manufactured according to some implementations.

The molybdenum film under observation in FIGS. 4 and 5 is a thin film deposited at 200° C. by using the BEBMo precursors and water (H₂O).

Referring to FIG. 4, it can be seen that the composition of the thin film manufactured by using the BEBMo precursors and water (H₂O) according to some implementations generally includes molybdenum (Mo) and carbon (C), and the thin film manufactured by using the BEBMo precursors and water (H₂O) is the molybdenum film.

Referring to FIG. 5, it can be seen that the composition of the thin film manufactured by using the BEBMo precursors and water (H₂O) according to some implementations generally includes molybdenum (Mo) and carbon (C). In particular, a relatively high-quality molybdenum film may be obtained, in which the molybdenum (Mo) ratio is about 60 at % or more and the oxygen (O) ratio is about 20 at % or less.

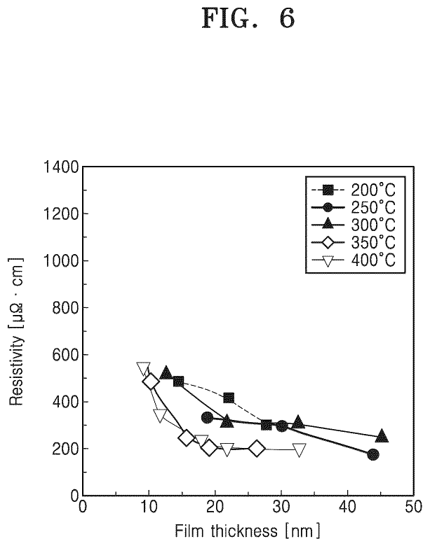

FIG. 6 is a graph showing the resistivity according to the thickness of the molybdenum film manufactured according to some implementations.

Specifically, FIG. 6 shows the resistivity measured after depositing a molybdenum film of a certain thickness on a TiN substrate at each of process temperatures of about 200° C., 250° C., 300° C., 350° C., and 400° C. in a molybdenum film deposition process.

Referring to FIG. 6, it can be seen that the molybdenum film manufactured by using the BEBMo precursors and water (H₂O) according to the manufacturing method of the present disclosure has a relatively low resistivity of about 202 μΩ×cm to about 413 μΩ×cm in a thickness range of about 5 nm to about 50 nm depending on the process temperatures.

Molybdenum (Mo) has a relatively low electron mean free path (EMFP) compared to copper (Cu) or tungsten (W) and may thus effectively suppress the size effect of resistivity in microfabricated elements. Therefore, the low resistivity may be obtained even in the thickness range of about 5 nm to about 50 nm.

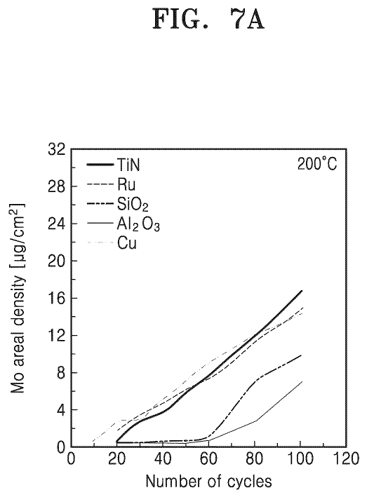

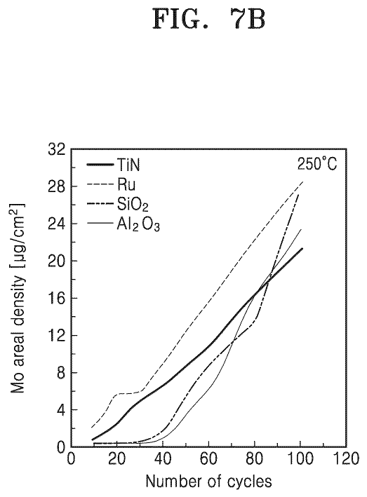

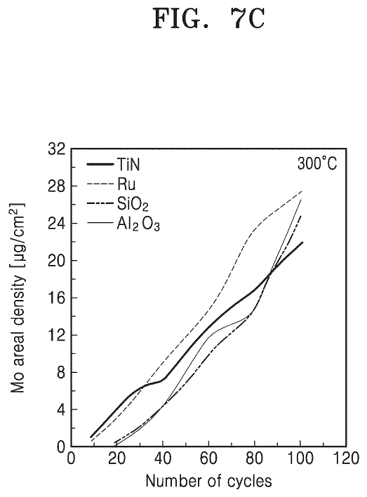

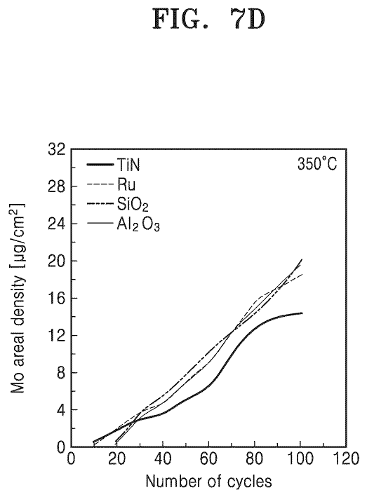

FIGS. 7A to 7D are graphs showing the nucleation delay according to the number of cycles for each process temperature in the ALD process for forming the molybdenum films.

Specifically, FIG. 7A is a graph when the ALD process is performed to form the molybdenum film at about 200° C., FIG. 7B is a graph when the ALD process is performed to form the molybdenum film at about 250° C., FIG. 7C is a graph when the ALD process is performed to form the molybdenum film at about 300° C., and FIG. 7D is a graph when the ALD process is performed to form the molybdenum film at about 350° C.

Referring to FIGS. 7A to 7D, in the case of a molybdenum film deposited on a conductive film containing TiN, Ru, or Cu and in the case of a molybdenum film deposited on an insulating film containing SiO₂ or Al₂O₃, the number of molybdenum (Mo) atoms per unit area, i.e., the areal density, is shown according to the number of repetitions of the cycle. In the process of depositing the molybdenum film on the conductive film, it can be seen that the areal density of molybdenum increases in proportion to the number of repetitions of the cycle. Also, in the process of depositing the molybdenum film on the insulating film, it can be seen that the areal density of molybdenum does not increase proportionally until a certain number of cycles, but then increases proportionally beyond the certain number of cycles. That is, in the process of depositing the molybdenum film on the insulating film, it can be assumed that a nucleation delay occurs up to a certain number of cycles.

When the molybdenum film is deposited on the insulating film containing SiO₂ or Al₂O₃, compared to when the molybdenum film is deposited on the conductive film containing TiN, Ru, or Cu, it can be seen that a nucleation delay occurs until about 60 cycles at about 200° C. as shown in FIG. 7A, a nucleation delay occurs until about 40 cycles at about 250° C. as shown in FIG. 7B, a nucleation delay occurs until about 20 cycles at about 300° C. as shown in FIG. 7C, and a nucleation delay occurs until about 10 cycles at about 350° C. as shown in FIG. 7D.

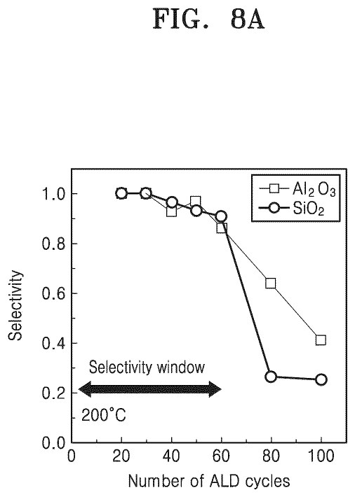

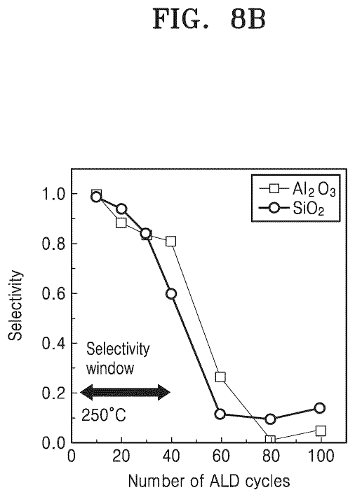

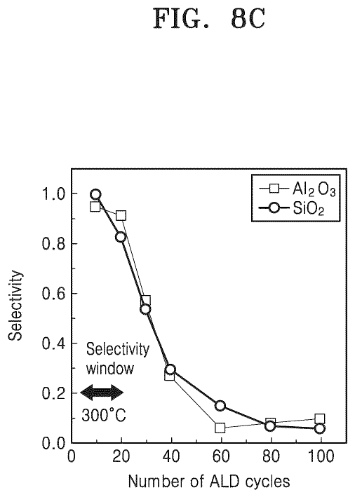

FIGS. 8A to 8C are graphs showing the areal selectivity according to the number of cycles for each process temperature in the ALD process for forming the molybdenum films.

Specifically, for the selectivity of molybdenum films deposited on TiN compared to molybdenum films deposited on Al₂O₃ or SiO₂, FIG. 8A shows the measurement results at about 200° C., FIG. 8B shows the measurement results at about 250° C., and FIG. 8C shows the measurement results at about 300° C., according to the number of cycles. The selectivity may be obtained from Equation 1 below.

$$S = \frac{{θ}_{GA} - {θ}_{NGA}}{{θ}_{GA} + {θ}_{NGA}} \qquad [ Equation 1 ]$$

In Equation 1 above, S represents selectivity, θ_{GA} represents an amount of a molybdenum film deposited on a growth region (e.g., a conductive film, TiN), and θ_{NGA} represents an amount of a molybdenum film deposited on a non-growth region (e.g., an insulating film, Al₂O₃ or SiO₂). The amount of the molybdenum film deposited may represent the number of molybdenum (Mo) atoms per unit area, that is, the areal density.

Referring to FIGS. 8A to 8C, it can be seen that a selectivity window narrows as the process temperature increases from about 200° C. to about 300° C. In the description with reference to FIGS. 7A to 7D, the maximum number of cycles in which the nucleation delay occurs is described. It can be seen that, even in FIG. 8A, relatively high selectivity is obtained until about 60 cycles at about 200° C., and even in FIG. 8B, relatively high selectivity is obtained until about 40 cycles at about 250° C. Also, as illustrated in FIG. 8C, it can be seen that relatively high selectivity is obtained until about 20 cycles at about 300° C.

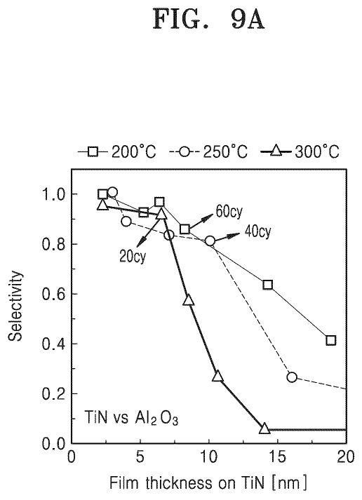

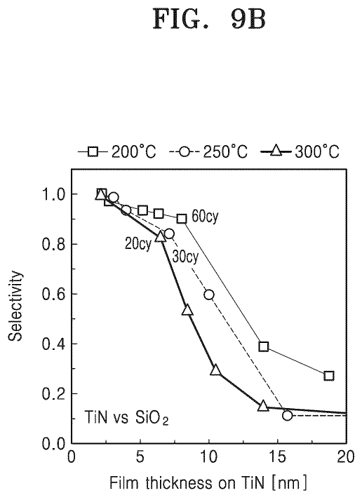

FIGS. 9A and 9B are graphs showing the areal selectivity according to the thickness of the molybdenum film for each of the materials constituting a first region and a second region of a substrate on which a molybdenum film is deposited in the ALD process for forming the molybdenum films.

Specifically, FIG. 9A is a graph showing the selectivity when the molybdenum film is deposited on the Al₂O₃ compared to when the molybdenum film is deposited on the TiN. Also, FIG. 9B is a graph showing the selectivity when the molybdenum film is deposited on the SiO₂ compared to when the molybdenum film is deposited on the TiN. The selectivity is calculated by using the same equation as Equation 1 described with reference to FIGS. 8A to 8C.

Referring to FIG. 9A, it can be seen that, when the molybdenum film is deposited on Al₂O₃ compared to when the molybdenum film is deposited on TiN, the selectivity of about 0.8 to about 1.0 is obtained until about 60 cycles at a process temperature of about 200° C. That is, at the process temperature of about 200° C., the selectivity of about 0.8 to about 1.0 may be obtained until the molybdenum film has a maximum thickness of about 7 nm to about 10 nm. At the process temperature of about 250° C., it can be seen that the selectivity of about 0.8 to about 1.0 is obtained until about 40 cycles. That is, at the process temperature of about 250° C., the selectivity of about 0.8 to about 1.0 may be obtained until the molybdenum film has a maximum thickness of about 5 nm to about 10 nm. At the process temperature of about 300° C., it can be seen that the selectivity of about 0.8 to about 1.0 is obtained until about 20 cycles. That is, at the process temperature of about 300° C., the selectivity of about 0.8 to about 1.0 may be obtained until the molybdenum film has a maximum thickness of about 2 nm to about 7 nm.

Based on the graphs shown in FIGS. 7A to 7D, 8A to 8C, 9A, and 9B, it has been identified that the maximum numbers of repetitions of the cycles and the maximum thicknesses of the molybdenum films, which exhibit the selectivity of about 0.8 to about 1.0, vary according to the process temperatures.

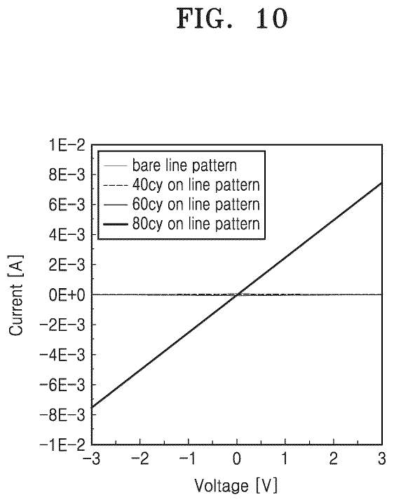

FIG. 10 is a graph showing current measured according to voltage on an insulating film to identify the selectivity according to the number of cycles in the ALD process for forming the molybdenum films.

Specifically, FIG. 10 shows the measurement results of the current according to the voltage on the insulating film after depositing the molybdenum film on the insulating film at the process temperature of about 200° C.

Referring to FIG. 10, when the molybdenum film is deposited for 40 cycles (40 cy on line pattern) and when the molybdenum film is deposited for 60 cycles (60 cy on line pattern), no current flows (0E+0), and thus, it can be assumed that no molybdenum film is deposited on the insulating film. That is, it can be assumed that, until about 60 cycles at about 200° C., relatively high selectivity for each area is obtained during the deposition of the molybdenum film. On the other hand, when the molybdenum film is deposited for 80 cycles (80 cy on line pattern), current flows (−8E-3), and thus, it can be assumed that the molybdenum film is deposited on the insulating film. That is, from about 80 cycles at about 200° C., it can be assumed that relatively very low selectivity for each area is obtained during the deposition of the molybdenum film.

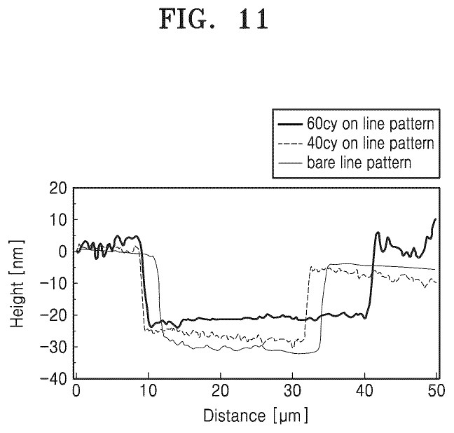

FIG. 11 is a graph showing a height (a Z height) measured in an atomic force microscopy (AFM) image according to the number of cycles to identify the areal selectivity in the ALD process for forming the molybdenum films.

Specifically, a molybdenum film is deposited on a substrate, which includes a first region having a conductive film and a second region having an insulating film, at a process temperature of about 200° C. FIG. 11 shows the results of sequential measurement of the height of a structure before deposition of the molybdenum film (bare line pattern), the height of a structure after 40 repetitions of the cycle for deposition of the molybdenum film (40 cy on line pattern), and the height of a structure after 60 repetitions of the cycle for deposition of the molybdenum film (60 cy on line pattern).

In FIG. 11, the range of 0 μm to about 10 μm and the range of about 30 μm to about 50 μm represent the second region including the insulating film, and the range of about 10 μm to about 30 μm represents the first region including the conductive film.

Referring to FIG. 11, in the range of the second region, the height of the structure before deposition of the molybdenum film, the height of the structure after 40 repetitions of the cycle for deposition of the molybdenum film, and the height of the structure after 60 repetitions of the cycle for deposition of the molybdenum film do not increase but remain generally constant as the number of cycles increases. In the range of the first region, it can be seen that the height of the structure before deposition of the molybdenum film, the height of the structure after 40 repetitions of the cycle for deposition of the molybdenum film, and the height of the structure after 60 repetitions of the cycle for deposition of the molybdenum film increase as the number of cycles increases.

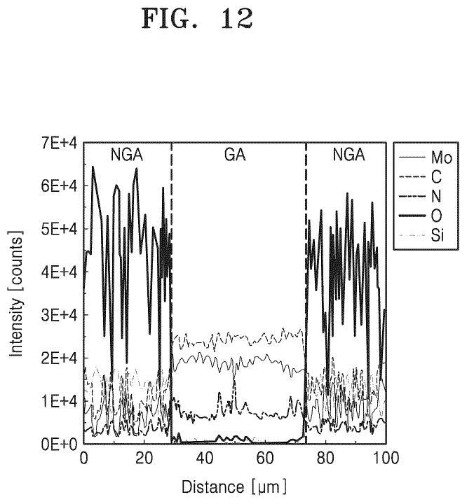

FIG. 12 is a graph showing results of Auger electron spectroscopy (AES) to identify the areal selectivity in the ALD process for forming the molybdenum films.

In FIG. 12, the range of 0 μm to about 30 μm and the range of about 70 μm to about 100 μm represent a second region (a non-growth area (NGA)) including an insulating film, and the range of about 30 μm to about 70 μm represents a first region (a growth area (GA)) including a conductive film. The first region includes TiN and the second region includes SiO₂. The process temperature is about 200° C., and the cycle is performed 60 times.

Referring to FIG. 12, in the range of the second region, the intensities of peaks representing silicon (Si) and oxygen (O) are high, and the intensities of peaks representing molybdenum (Mo) and carbon (C) are low. Based on this, it can be assumed that no molybdenum film has been deposited in the range of the second region. In the range of the first region, the intensities of peaks representing molybdenum (Mo) and carbon (C) are high. Based on this, it can be assumed that a molybdenum film has been deposited in the range of the first region.

Hereinafter, the analysis results of characteristics of the molybdenum film manufactured by heat treatment under the hydrogen atmosphere according to other implementations described with reference to FIG. 3 are described. It is assumed that the molybdenum film subjected to heat treatment under the hydrogen atmosphere below is deposited by using the BEBMo precursors and water (H₂O) at about 250° C.

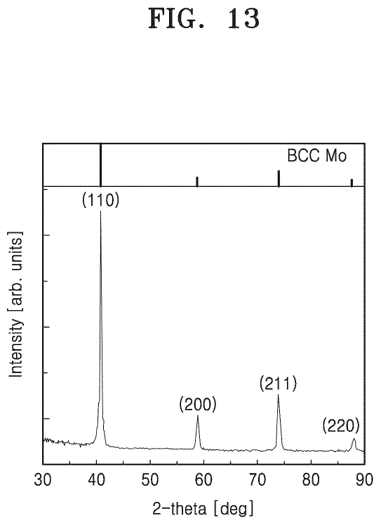

FIG. 13 is a graph showing the results of X-ray diffraction (XRD) analysis to explain a crystalline phase of the molybdenum film that has been heat-treated under the hydrogen atmosphere.

Referring to FIG. 13, it can be seen that 2θ values of peaks in X-ray diffraction analysis results of molybdenum having a generally known body-centered cubic (BCC) structure are equal to 2θ values of peaks in X-ray diffraction analysis results shown in FIG. 13. Accordingly, it can be seen that the molybdenum film is reduced to molybdenum having a BCC structure by the heat treatment under the hydrogen atmosphere.

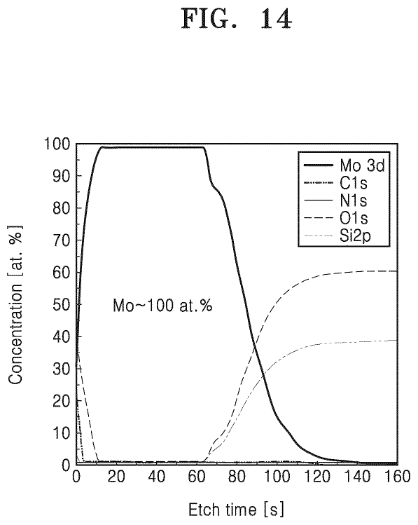

FIG. 14 is a graph showing changes in concentration according to etch time to explain chemical compositions of the molybdenum film that has been heat-treated under the hydrogen atmosphere.

Referring to FIG. 14, it can be seen that the composition of the thin film manufactured by using the BEBMo precursors and water (H₂O) and heat-treated under the hydrogen atmosphere generally includes molybdenum (Mo). In particular, a relatively high-quality molybdenum film may be obtained, in which the molybdenum (Mo) ratio is about 95 at % to about 100 at % and the oxygen (O) ratio is 0 at % to about 5 at %.

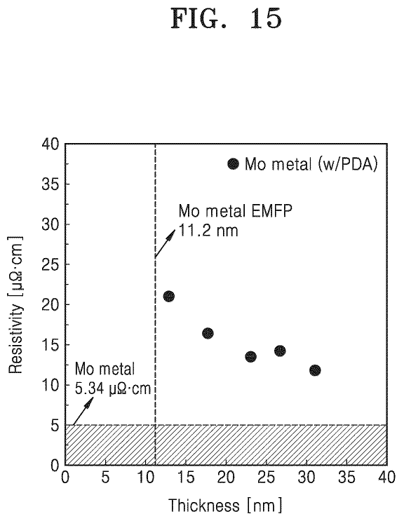

FIG. 15 is a graph showing the resistivity according to the thickness of the molybdenum film that has been heat-treated under the hydrogen atmosphere.

Referring to FIG. 15, the resistivity of molybdenum (Mo) is 5.34 μΩ×cm, and the EMFP of molybdenum (Mo) is 11.2 nm. It can be seen that the molybdenum film heat-treated under the hydrogen atmosphere has low resistivity of about 25 μΩ×cm to about 10 μΩ×cm at the thickness of about 10 nm to about 35 nm. Molybdenum (Mo) has a relatively low EMFP compared to copper (Cu) or tungsten (W) and may thus effectively suppress the size effect of resistivity in microfabricated elements. Therefore, the low resistivity may be obtained even in the thickness range of about 10 nm to about 35 nm.

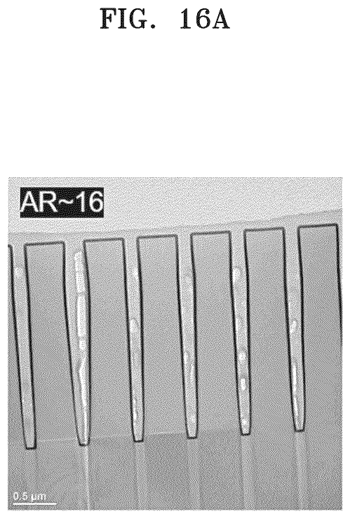

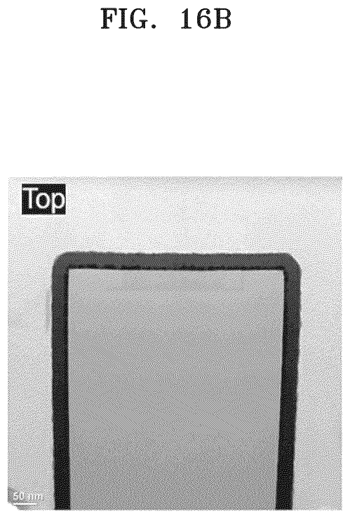

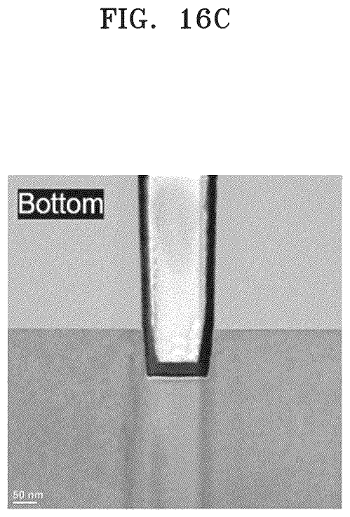

FIGS. 16A to 16C are transmission electron microscopy (TEM) images for identifying step coverage of the molybdenum film manufactured according to implementations.

Specifically, FIG. 16B is an enlarged view of the top portion of a structure having a high aspect ratio as shown in FIG. 16A. Also, FIG. 16C is an enlarged view of the bottom portion of the structure having the high aspect ratio as shown in FIG. 16A.

Referring to FIGS. 16A to 16C, it can be seen that the molybdenum film manufactured according to some implementations has a generally uniform thickness from the top to the bottom. In order to check the step coverage of the molybdenum film, a percentage ratio of the thickness of the molybdenum film at the bottom to the thickness of the molybdenum film at the top is calculated, and it is identified that the step coverage is relatively high at about 92.2%.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to example implementations thereof, it will be understood that various changes in form and details may be made therein without departing from the spirit and scope of the following claims.

What is claimed is:

1. A method of manufacturing a molybdenum film by repeatedly performing a cycle, wherein the cycle comprises:
injecting a molybdenum precursor onto a substrate comprising a first region and a second region, thereby forming a chemisorption layer of the molybdenum precursor;
supplying a first purge gas onto a first resulting structure in which the chemisorption layer of the molybdenum precursor has been formed;
supplying a reducing agent containing water (H₂O) onto the chemisorption layer of the molybdenum precursor, thereby forming a molybdenum thin film; and
supplying a second purge gas onto a second resulting structure in which the molybdenum thin film has been formed.

2. The method of claim 1, wherein the molybdenum precursor comprises a bis(ethylbenzene)molybdenum (BEBMo) precursor.

3. The method of claim 1, wherein the cycle is performed at a temperature in a range of about 150° C. to about 400° C., and
the manufactured molybdenum film has resistivity of about 100 μΩ×cm to about 600 μΩ×cm.

4. The method of claim 1, wherein the cycle is performed 1 time to 60 times at a temperature in a range of about 200° C. to about 350° C.

5. The method of claim 1, wherein the first region of the substrate comprises a conductive film, and the second region of the substrate comprises an insulating film, and
wherein the chemisorption layer of the molybdenum precursor is formed on the first region of the substrate.

6. The method of claim 1, comprising performing, under a hydrogen atmosphere, heat treatment on the molybdenum film formed by repeating the cycle.

7. The method of claim 6, wherein the hydrogen atmosphere comprises about 5% to 15% of hydrogen (H₂) gas and about 85% to about 95% of argon (Ar) gas.

8. The method of claim 6, wherein the heat treatment is performed at a pressure of about 7 torr to about 9 torr and at a maximum temperature of about 750° C. to about 850° C.

9. The method of claim 1, wherein the molybdenum film formed by repeatedly performing the cycle comprises about 60 at % to about 100 at % of molybdenum and about 20 at % to about 40 at % of carbon.

10. The method of claim 1, wherein the molybdenum film formed by repeatedly performing the cycle comprises 0 at % to about 20 at % of oxygen.

11. A method of manufacturing a molybdenum film by repeatedly performing a cycle, wherein the cycle comprises:
injecting a bis(ethylbenzene)molybdenum (BEBMo) precursor onto a substrate comprising a first region and a second region, thereby forming a chemisorption layer of the BEBMo precursor;
supplying a first purge gas onto a first resulting structure in which the chemisorption layer of the BEBMo precursor has been formed;
supplying a reducing agent onto the chemisorption layer of the BEBMo precursor, thereby forming a molybdenum thin film; and
supplying a second purge gas onto a second resulting structure in which the molybdenum thin film has been formed,
wherein the first region of the substrate comprises a conductive film,
wherein the second region of the substrate comprises an insulating film, and
wherein the chemisorption layer of the BEBMo precursor is formed on the first region of the substrate.

12. The method of claim 11, wherein the reducing agent comprises water (H₂O).

13. The method of claim 11, wherein the cycle is performed 1 time to 60 times at a temperature in a range of about 200° C. to about 350° C., and
wherein during the cycle, the chemisorption layer of the BEBMo precursor has selectivity for the first region relative to the second region of the substrate.

14. The method of claim 13, wherein a maximum number of repetitions of the cycle in which the BEBMo precursor has the selectivity for the first region of the substrate is inversely proportional to a process temperature at which the cycle is performed.

15. The method of claim 11, comprising performing, under a hydrogen atmosphere, heat treatment on the molybdenum film formed by repeating the cycle,
wherein the hydrogen atmosphere comprises about 5% to 15% of hydrogen (H₂) gas and about 85% to 95% of argon (Ar) gas.

16. The method of claim 15, wherein the heat treatment is performed at a pressure of about 7 torr to about 9 torr and at a maximum temperature of 800° C.,
wherein a total time of the heat treatment is in a range of about 170 seconds to about 200 seconds, and
wherein the heat treatment is performed by raising a temperature at a certain rate of degrees Celsius per second (° C./sec) from a first temperature to the maximum temperature.

17. The method of claim 11, wherein the molybdenum film formed by repeatedly performing the cycle comprises about 60 at % to about 100 at % of molybdenum, about 20 at % to about 40 at % of carbon, and 0 at % to about 20 at % of oxygen.

18. A method of manufacturing a molybdenum film by repeatedly performing a cycle, wherein the cycle comprises:
injecting a bis(ethylbenzene)molybdenum (BEBMo) precursor onto a substrate comprising a first region and a second region, thereby forming a chemisorption layer of the BEBMo precursor;
supplying a first purge gas onto a first resulting structure in which the chemisorption layer of the BEBMo precursor has been formed;
supplying a reducing agent containing water (H₂O) onto the chemisorption layer of the BEBMo precursor, thereby forming a molybdenum thin film; and
supplying a second purge gas onto a second resulting structure in which the molybdenum thin film has been formed,
wherein the first region of the substrate comprises a conductive film,
wherein the second region of the substrate comprises an insulating film, and
wherein the chemisorption layer of the BEBMo precursor has selectivity for the first region relative to the second region of the substrate.

19. The method of claim 18, wherein the chemisorption layer of the BEBMo precursor has selectivity for the first region relative to the second region of the substrate in a range of 1 time to 60 times of the cycle at a temperature in a range of about 200° C. to about 350° C., and
wherein a number of times of the cycle in which the BEBMo precursor has the selectivity for the first region of the substrate is inversely proportional to a process temperature at which the cycle is performed.

20. The method of claim 18, comprising performing, under a hydrogen atmosphere, heat treatment on the molybdenum film formed by repeating the cycle,
wherein the hydrogen atmosphere comprises about 5% to 15% of hydrogen (H₂) gas and about 85% to 95% of argon (Ar) gas, and
wherein the heat treatment is performed at a pressure of about 7 torr to about 9 torr and at a maximum temperature of 800° C.
